(19) United States
(12) Patent Application Publication
(10) Pub. No.: US 2010/0230784 A1
(43) Pub. Date: Sep. 16, 2010

(54) Semiconductor Packaging with Integrated Passive Componentry

(75) Inventors: Ross E. Teggatz, McKinney, TX (US); Wayne T. Chen, Plano, TX (US); Brett Smith, Richardson, TX (US)

Correspondence Address: MICHAEL T. KONCZAL, PATENT ATTORNEY, P.O. BOX 863656, PLANO, TX, 75086, US

(73) Assignee: TRIUNE IP LLC, Richardson, TX (US)

(21) Appl. No.: 12/725,274

(22) Filed: Mar. 16, 2010

Related U.S. Application Data
(60) Provisional application No. 61/160,686, filed on Mar. 16, 2009.

(51) Int. Cl. H01L 23/52; H01L 27/06; H01L 23/28

(52) U.S. Cl. 257/531; 257/532; 257/723; 257/528; 257/E27.011; 257/E23.141; 257/E23.116

(57) ABSTRACT

The invention provides advances in the arts with useful and novel integrated packaging having passive components included within packages also containing one or more ICs. The integrated passive components may include inductors, transformers, and capacitors, and are preferably constructed of leadframe materials. Typically, one or more magnetic field storage body is used in forming the coils in order to enhance the electrical performance characteristics of the passive component.

### PRIORITY ENTITLEMENT

This application is entitled to priority based on Provisional Patent Application Ser. No. 61/160,686 filed on Mar. 16, 2009, which is incorporated herein for all purposes by this reference. This application and the Provisional Patent Application have at least one common inventor.

### TECHNICAL FIELD

The invention relates to integrated circuits (ICs) and packaging. More particularly, the invention relates to integrated semiconductor device packaging having one or more passive components encapsulated within the same package as one or more ICs.

### BACKGROUND OF THE INVENTION

It is well known in the arts that it is often necessary to electrically couple passive components with integrated circuits (ICs) in order to make the ICs function in a given system. Such passive components include inductors, capacitors, and resistors, as well as their derivatives, such as transformers, chokes, and isolation structures, to name a few. The inclusion of separate passive components and ICs can lead to problems in the design and assembly of electronic apparatus. Using separate components, designers and assemblers must select and install the correct components for proper functioning. Printed circuit board (PCB) layout complexity may be increased due to the need to provide space for passive components for use alongside ICs. In some cases, the inclusion of passive components may be essential to the proper functioning of a particular component, with the result that the design and assembly processes require planning for the inclusion of two or three parts for simulation, design, purchasing, assembly, testing etc., instead of just one. Particularly in complex microelectronic systems, the increased part count can lead to higher costs and/or lower yields.

In electronic systems, it would be desirable to integrate passive components, insofar as practical, into a single package along with an IC. With the appropriate passive component(s) integrated into a package with an IC, users would not be required to select the correct passive component(s) to match to the IC. In many cases, PCB layout complexity would be reduced as fewer components and routes would be required on the board, and component count would be reduced, simplifying some steps in the design and development processes. To cite one example, implementing a system that includes a switched-mode power supply (SMPS) requires both an inductor and a capacitor on the output to produce a regulated voltage. Including the appropriate inductor and capacitor components in the same package with the SMPS would be an improvement.

### SUMMARY OF THE INVENTION

In carrying out the principles of the present invention, in accordance with preferred embodiments, the invention provides advances in the arts with useful and novel integrated packaging having passive components included within packages containing one or more ICs. Preferably, the integrated passive components according to the invention are constructed of materials, such as leadframe materials, adapted from those available in the practice of the applicable arts. Variations in the practice of the invention are possible and preferred embodiments are illustrated and described. All possible variations within the scope of the invention cannot, and need not, be shown. It should be understood that the invention may be used with various package and PCB layout formats.

According to one aspect of the invention, in an example of a preferred embodiment, a semiconductor device package includes an integrated passive component having a coil. The coil is inductive and has ends for electrically coupling within a circuit. At least one magnetic field storage bodies is positioned adjacent to the coil for storing one or more magnetic fields for increasing the inductance of the coil. The coil and magnetic field storage body are encapsulated within a single semiconductor device package.

According to another aspect of the invention, a preferred embodiment of a semiconductor device package incorporating integrated passive componentry includes a coil having a magnetic field storage body extending across a plurality of conductive leads and encircled by conductive elements electrically connected to alternate leads on opposite sides of the magnetic field storage body. The whole is encapsulated within a single integrated package.

According to another aspect of the invention, a semiconductor device package includes an integrated transformer of two or more coils coupled in series, each coil further comprising a magnetic field storage body extending across a plurality of conductive leads and encircled by conductive coupling elements electrically connected to alternate leads on opposite sides of the magnetic field storage body.

According to yet another aspect of the invention, embodiments as exemplified herein may be implemented wherein the conductive coupling elements further comprises routing dies or bondwires.

According to another aspect of the invention, in an example of a preferred embodiment, a semiconductor device package includes an integrated capacitor including a first plate, a separating gap, and a second plate. One or more integrated circuits are operably coupled to one or more of the capacitor plates; and the capacitor and one or more integrated circuits are encapsulated within a single semiconductor device package.

The invention has advantages including but not limited to providing one or more of the following features, conservation of board area, simplified design and layout, improved efficiency and reduced costs. These and other advantageous, features, and benefits of the invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the description and drawings in which:

FIG. 1 is a top view of an example of a preferred embodiment of semiconductor packaging with an integrated passive component;

FIG. 2 is a side view of an example of a preferred embodiment of semiconductor packaging with an integrated passive component;

FIG. 3 illustrates an example of an alternative preferred embodiment of a semiconductor package with an integrated passive component;

FIG. 4 illustrates an example of an alternative preferred embodiment of a semiconductor package with an integrated passive component;

FIG. 5 provides a top view of an example of an alternative preferred embodiment of semiconductor packaging with an integrated passive component;

FIG. 6 is a side view of an example of a preferred embodiment of semiconductor packaging with an integrated passive component;

FIG. 7 is a top view of an example of a preferred embodiment of semiconductor packaging with integrated passive components connected in series;

FIG. 8 is a top view of an example of an alternative preferred embodiment of semiconductor packaging with integrated passive components;

FIG. 9 illustrates an example of an alternative preferred embodiment of a semiconductor package with an integrated passive component, namely a transformer;

FIG. 10 provides a top view of an example of an alternative structure for a preferred embodiment of semiconductor packaging with an integrated passive component;

FIG. 11 is a side view of an example of an alternative structure preferred embodiment of semiconductor packaging with an integrated passive component;

FIG. 12 is a top view of another example of a preferred embodiment of semiconductor packaging with an integrated passive component; and

FIG. 13 is a side view of the example of a preferred embodiment of semiconductor packaging with an integrated passive component introduced with reference to FIG. 12.

References in the detailed description correspond to like references in the various drawings unless otherwise noted. Descriptive and directional terms used in the written description such as front, back, top, bottom, upper, side, et cetera, refer to the drawings themselves as laid out on the paper and not to physical limitations of the invention unless specifically noted. The drawings are not to scale, and some features of embodiments shown and discussed are simplified or amplified for illustrating principles and features as well as anticipated and unanticipated advantages of the invention.

### DESCRIPTION OF PREFERRED EMBODIMENTS

While the making and using of various exemplary embodiments of the invention are discussed herein, it should be appreciated that the systems and methods exemplify inventive concepts which can be embodied in a wide variety of specific contexts. It should be understood that the invention may be practiced in various applications and embodiments without altering the principles of the invention. For purposes of clarity, detailed descriptions of functions, components, and systems familiar to those skilled in the applicable arts are not included. In general, the invention provides semiconductor packages for ICs with integrated passive circuit components such as inductors and capacitors. The invention is described in the context of representative example embodiments. Although variations in the details of the embodiments are possible, each has advantages over the prior art.

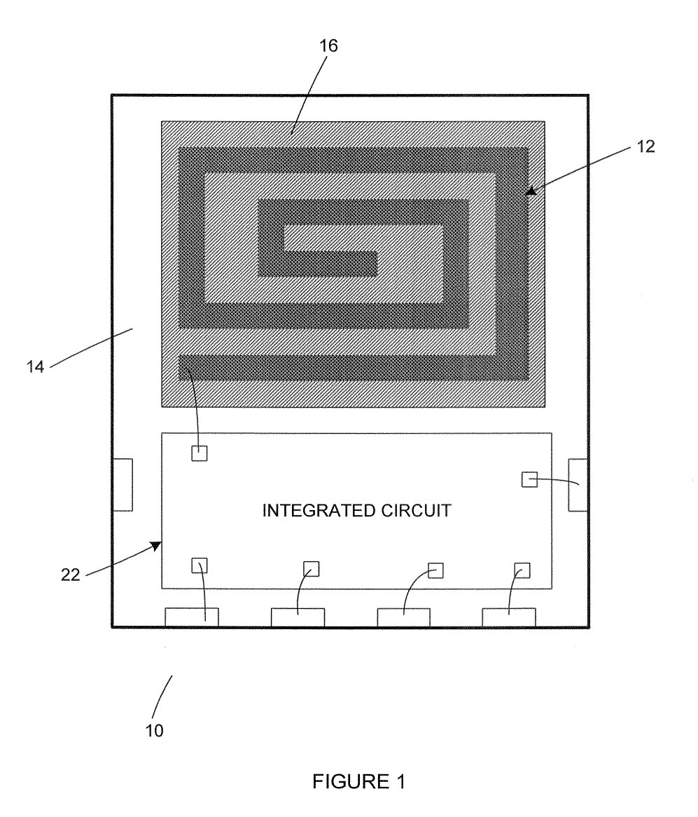

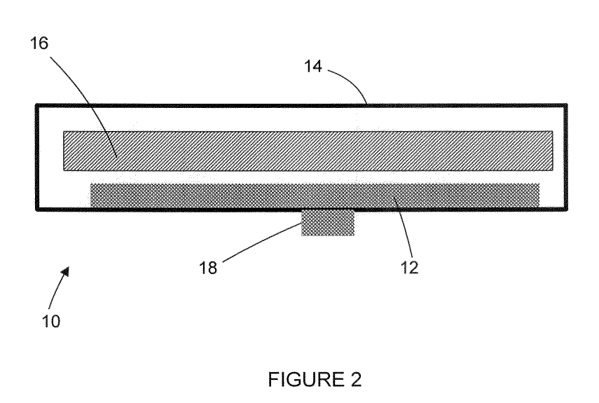

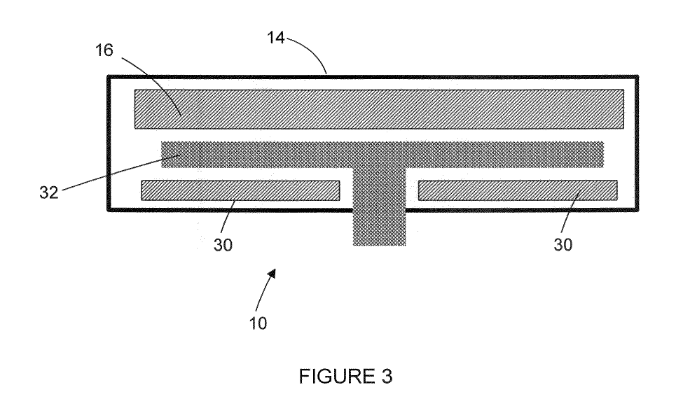

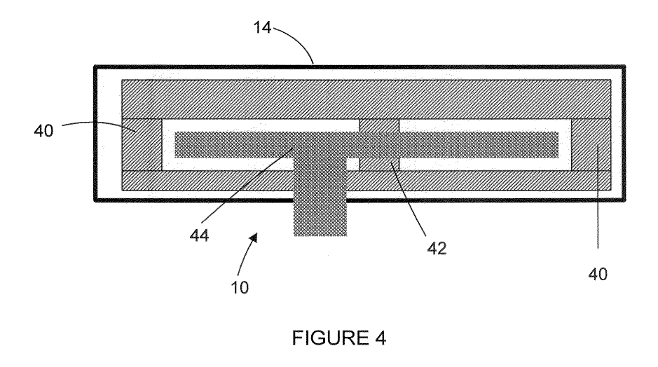

Referring initially to FIG. 1, an example of a preferred embodiment of an integrated package 10 is illustrated. In this top cut-away view, the package 10 is shown without encapsulant, exposing an inductor 12, preferably made from substantially planar leadframe material wound in a coil. In FIG. 2, a corresponding cut-away side view is shown with encapsulant 14 in place. The leadframe material 12 is adjacent to a magnetically permeable material 16 such as ferrite or similar substitute material possessing a magnetic field. Preferably, the ends of the inductor 12 are suitable for making electrical connections as needed for the particular application. For example, a first end 18 of the inductor coil 12 may be, or may be directly connected to, a package pin 18. As shown in this example, a second end 20 of the inductor 12 may be electrically connected with another device such as an IC 22, or in some cases, another passive component within the package. The ferrite 16 or other magnetically permeable material adjacent to the inductor coil 12 functions to store a magnetic field, enhancing inductance. Now referring to FIG. 3, additionally, or alternatively, magnetically permeable material 30 may also be added adjacent to the other side of the coil 32. As shown in FIG. 4, the inductance may be further enhanced by adding permeable magnetic material at the sides 40 and center 42 of the coil 44. It should also be understood that the inductance may be further enhanced by the addition of magnetically permeable material to a mount pad or other part of the PCB (not shown) to which the integrated package is to be mounted in order to further increase the inductance. An example of the use of a package according to FIGS. 1 and 2 is a power or data signal isolation system in which two similar packages may be placed with inductors back-to-back. Preferably, in such placement, the inductors are electrically isolated but are nevertheless aligned for the transfer of a signal from one to the other, such as a power or data signal. Similarly, back-to-back inductors may be included within the same package, providing a signal link having electrical isolation.

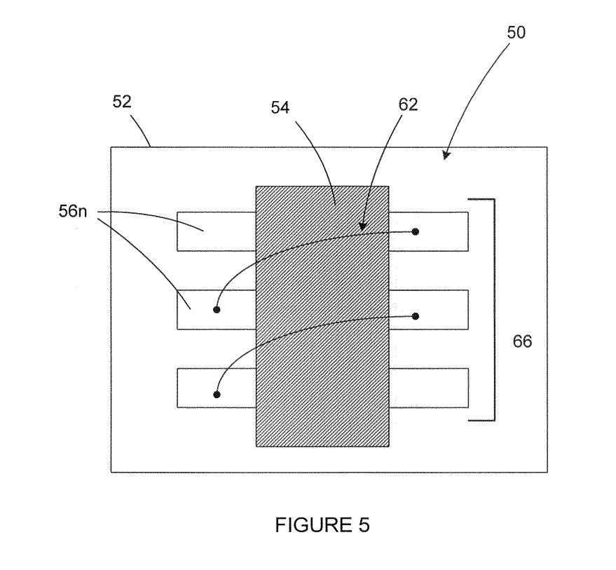

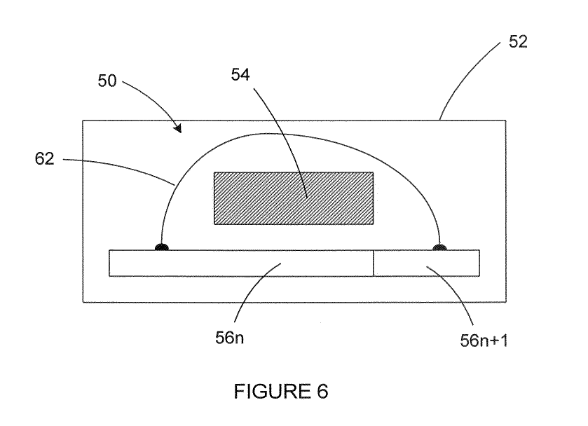

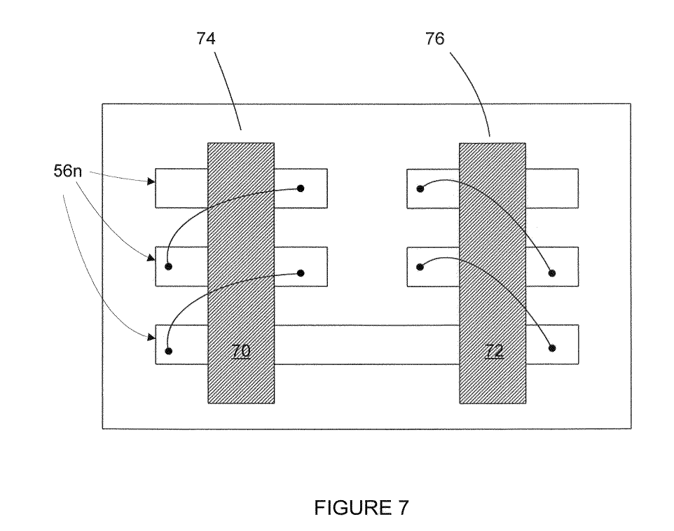

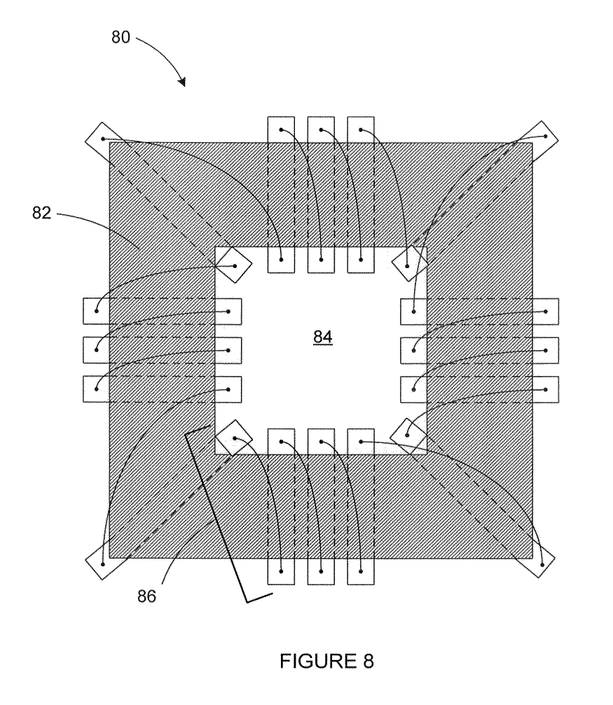

In an alternative embodiment of the invention, an example of which is depicted in FIG. 5, an inductor 50 may be integrated within a package 52. Preferably, a rod or bar 54 of magnetically permeable material is placed so as to extend across a number of conductive leads 56n, as on a leadframe. This embodiment is also shown in a cutaway side view in FIG. 6. Forming a wire-wound inductor 50, electrical coupling elements, such as the bondwires 62 shown, make connections from each lead 56n of the leadframe material to the next 56n+1, crossing over the magnetically permeable material 54 and forming a winding 66 around the magnetically permeable material 54. In a variation of this embodiment, shown in the top view of FIG. 7, more than one bar of magnetically permeable material e.g., 70, 72, may be used to form a series of inductors 74, 76, providing increased inductance. An additional alternative embodiment is shown in FIG. 8. The inductor 80 may be formed using a magnetically permeable material 82 formed in the shape of a continuous geometric figure such as a rectangle, square, torus, or other shape, preferably having an aperture 84 to facilitate windings 86.

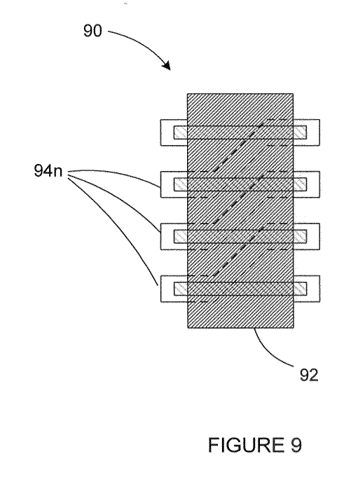

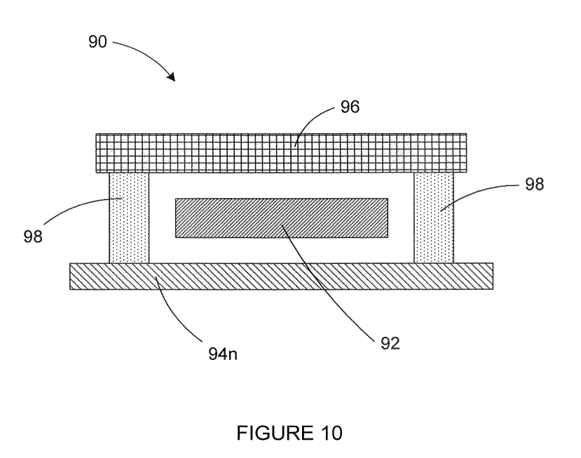

In the preferred embodiments of packages including integrated passive components discussed above, bondwires are shown and described as forming the electrical coupling elements between leads, which complete the coil windings around a magnetically permeable material. An alternative embodiment is shown in FIGS. 9 and 10. A magnetically permeable material 92, such as a bar of ferrite, is shown positioned adjacent to leads 94n on a leadframe. Making the connections extending over the magnetically permeable material 92 between the alternating leads 94n, a routing die 96, shown in FIG. 10, is used. Preferably, the routing die 96 is prepared for making the appropriate connections and installed in the manner of a flip-chip over the magnetically permeable material 92. Preferably, the leads 94 have vertical extensions or posts 98 in order to facilitate the connections with the appropriate points on the routing die 98. One particular advantage of this embodiment is the close proximity of the routing die 98 with the magnetically permeable material 92, which increases the inductance of the structure 90.

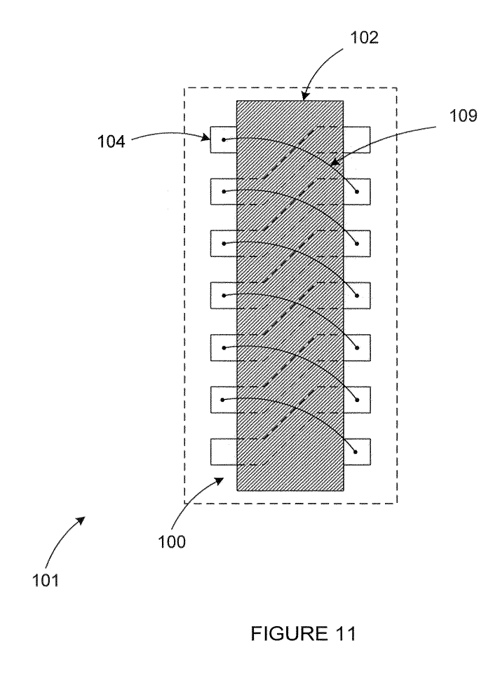

A transformer 100, shown in FIG. 11, is an additional passive component that may be used in implementing semiconductor packaging with integrated passive componentry 101 in accordance with the invention. This alternative preferred embodiment may be constructed with a structure similar to that described and shown for inductors. The transformer 100 includes a ferromagnetic core 102 around which multiple coils, or windings 104, are wrapped. For the core 102, magnetically permeable material such as ferrite may be used. The windings 104 are preferably formed using a routing die or other electrical coupling elements such as bondwires 109. An input line is preferably connected to a ‘primary’ coil 104, and an output line connects to one or more ‘secondary’ coils. Alternating current in the primary coil induces an alternating magnetic flux that ‘flows’ around the ferromagnetic core, changing direction during each electrical cycle. The alternating flux in the core in turn induces an alternating current in the secondary coil(s).

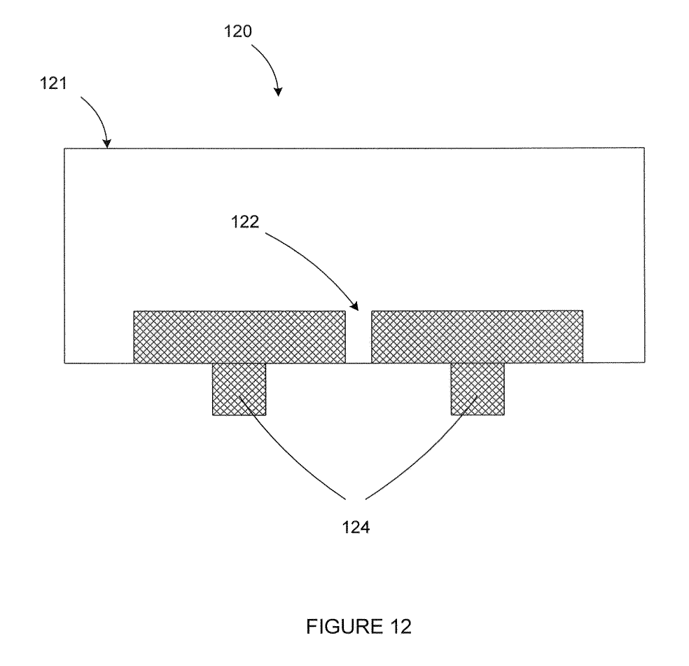

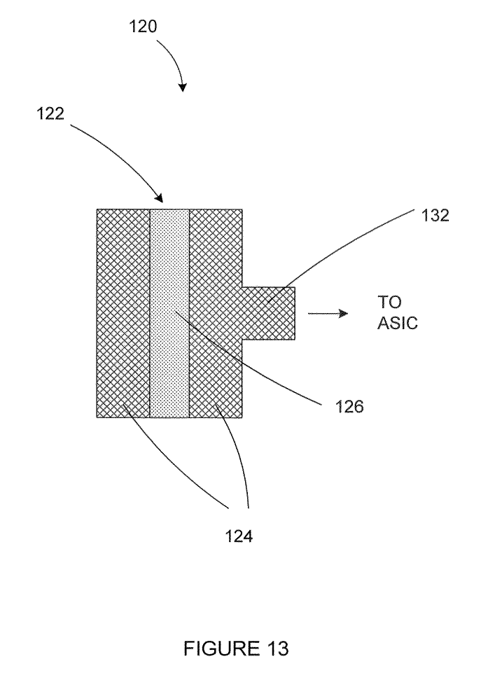

Capacitors may also, or alternatively, be included as integrated passive components in semiconductor packages. As depicted in FIGS. 12 and 13, a capacitor 120 is preferably formed by introducing an appropriate gap 122 between leadframe materials 124 enclosed within the encapsulant 121. Those skilled in the arts will recognize that capacitance can be increased by or decreased by increasing or decreasing the surface area of the materials adjacent to the gap. The gap may be vertical or horizontal and achieved through a selective etch process. Dielectric material 126 may also be added in the gap to create a higher capacitance per unit area. As shown, first and second capacitor plates 124 preferably have one or more contacts 132 for electrically coupling within a circuit. In many implementations, one or more ICs, e.g., 30, are operably coupled to one or more of the capacitor terminals, or to an external circuit or system, typically through a package pin or bond pad, e.g., 132.

The systems and methods of the invention provide one or more advantages including but not limited to, conservation of board area, simplified design and implementation processes, reduced errors, and reduced costs. While the invention has been described with reference to certain illustrative embodiments, those described herein are not intended to be construed in a limiting sense. For example, variations or combinations of steps or materials in the embodiments shown and described may be used in particular cases without departure from the invention. Although the presently preferred embodiments are described herein in terms of particular examples, modifications and combinations of the illustrative embodiments as well as other advantages and embodiments of the invention will be apparent to persons skilled in the arts upon reference to the drawings, description, and claims.

We claim:

1. A semiconductor device package comprising:
a coil having an inductance and also having first and second ends for electrically coupling within a circuit;
one or more magnetic field storage bodies adjacent to the coil for storing one or more magnetic field whereby the one or more magnetic field storage bodies increase the inductance of the coil;
encapsulant encapsulating the coil and one or more magnetic field storage bodies within a single semiconductor device package.

2. A semiconductor device package according to claim 1 further comprising an integrated circuit operably coupled to the coil and encapsulated within the package.

3. A semiconductor device package according to claim 1 wherein a first end of the coil comprises a contact for receiving an electrical coupling from an external conductor to the package.

4. A semiconductor device package according to claim 1 wherein one or more magnetic field storage bodies further comprises ferrite.

5. A semiconductor device package according to claim 1 further comprising one or more magnetic field storage bodies affixed adjacent to an external surface of the encapsulant.

6. A semiconductor device package according to claim 1 wherein the coil is substantially planar.

7. A semiconductor device package according to claim 1 wherein the coil further comprises leadframe material.

8. A semiconductor device package according to claim 1 wherein the coil further comprises a magnetic field storage body extending across a plurality of conductive leads and encircled by conductive coupling elements electrically connected to alternate leads on opposite sides of the magnetic field storage body.

9. A semiconductor device package according to claim 1 wherein the coil further comprises a magnetic field storage body extending across a plurality of conductive leads and encircled by conductive coupling elements electrically connected to alternate leads on opposite sides of the magnetic field storage body, the magnetic field storage body substantially defining a bar shape.

10. A semiconductor device package according to claim 1 wherein the coil further comprises a magnetic field storage body extending across a plurality of conductive leads and encircled by conductive coupling elements electrically connected to alternate leads on opposite sides of the magnetic field storage body, the magnetic field storage body further comprising an enclosed geometric shape having an aperture.

11. A semiconductor device package according to claim 1 wherein the coil further comprises a magnetic field storage body extending across a plurality of conductive leads and encircled by conductive coupling elements electrically connected to alternate leads on opposite sides of the magnetic field storage body, the magnetic field storage body further comprising a substantially rectangular enclosed geometric shape having an aperture.

12. A semiconductor device package according to claim 1 wherein the coil further comprises a magnetic field storage body extending across a plurality of conductive leads and encircled by conductive coupling elements electrically connected to alternate leads on opposite sides of the magnetic field storage body, the magnetic field storage body further comprising a substantially toroid shape.

13. A semiconductor device package according to claim 1 further comprising a plurality of coils each further comprising a magnetic field storage body extending across a plurality of conductive leads and encircled by conductive coupling elements electrically connected to alternate leads on opposite sides of the magnetic field storage body.

14. A semiconductor device package according to claim 1 further comprising a plurality of coils coupled in series, each coil further comprising a magnetic field storage body extending across a plurality of conductive leads and encircled by conductive coupling elements electrically connected to alternate leads on opposite sides of the magnetic field storage body.

15. A semiconductor device package according to claim 1 further comprising a first coil coupled with a second coil operable in combination as a transformer.

16. A semiconductor device package according to claim 1 wherein one or more of the conductive coupling elements further comprise bondwires.

17. A semiconductor device package according to claim 1 wherein the conductive coupling elements further comprise a routing die.

18. A semiconductor device package comprising:
a capacitor having a first plate and a second plate separated by a gap, the first and second plate having terminals for electrically coupling within a circuit;
one or more integrated circuits operably coupled to one or more of the capacitor plates; and
encapsulant encapsulating the capacitor and one or more integrated circuits within a single semiconductor device package.

20. A semiconductor device package according to claim 18 further comprising one or more magnetic field storage bodies within the gap for increasing the capacitance of the capacitor.

21. A semiconductor device package according to claim 18 wherein one of the terminals comprises a pin for receiving an electrical coupling from an external conductor to the package.

22. A semiconductor device package according to claim 18 wherein one or more magnetic field storage bodies further comprises ferrite.

23. A semiconductor device package according to claim 18 wherein the first plate, second plate, and a magnetic field storage body are substantially planar.

24. A semiconductor device package according to claim 18 wherein the capacitor plates further comprises leadframe material.

25. A semiconductor device package comprising:
a first coil having an inductance and also having first and second ends for electrically coupling within a circuit;
a second coil having an inductance and also having first and second ends for electrically coupling within a circuit; wherein,
the first and second coils are positioned to be electrically isolated from one another; and
encapsulant encapsulating the first and second coils within a single semiconductor device package.

26. A semiconductor device package according to claim 25 wherein the first coil is positioned for data transfer to the second coil.

27. A semiconductor device package according to claim 25 wherein the first coil is positioned for power transfer to the second coil.

28. A semiconductor device package according to claim 25 further comprising at least one integrated circuit operably coupled to at least one of the first and second coils and encapsulated within the package.
